(19) United States
(12) Patent Application Publication
(10) Pub. No.: US 2024/0284608 A1
(43) Pub. Date: Aug. 22, 2024

(54) CIRCUIT BOARD, MANUFACTURING METHOD, AND DISPLAY MODULE

(71) Applicants: HongQiSheng Precision Electronics (QinHuangDao) Co., Ltd., Qinhuangdao (CN); Avary Holding (Shenzhen) Co., Limited., Shenzhen (CN); Garuda Technology Co., Ltd., New Taipei (TW)

(72) Inventors: Gang Yuan, Shenzhen (CN); Xiao-Juan Zhang, Qinhuangdao (CN)

(21) Appl. No.: 18/611,934

(22) Filed: Mar. 21, 2024

Related U.S. Application Data
(63) Continuation-in-part of application No. PCT/CN2023/076931, filed on Feb. 17, 2023.

(51) Int. Cl. H05K 5/00; H05K 1/05; H05K 1/11; H05K 3/00; H05K 3/40

(52) U.S. Cl. CPC H05K 5/0069; H05K 1/056; H05K 1/112; H05K 1/115; H05K 3/0094; H05K 3/4038; H05K 2201/09563; H05K 2201/10128; H05K 2203/0323

(57) ABSTRACT

A circuit board includes an inner wiring substrate and a first side plate. The inner wiring substrate includes a plurality of first connection pads at a side. The first side plate is disposed on the inner wiring substrate and defines a plurality of first holes exposing the first connection pads. Each first hole includes a first end facing the first connection pad and a second end facing away from the first connection pad. A central distance between two adjacent first connection pads is greater than a center distance between two second ends of two adjacent first holes. The first holes are filled with first conductive bodies, each first conductive body is electrically connected to the first connection pad and extends out of the first hole to form a connection portion. A method for manufacturing the circuit board and a display module are also disclosed.

### FIELD

The subject matter herein generally relates to display, in particular, to a circuit board, a manufacturing method thereof, and a display module.

### BACKGROUND

A display module includes a circuit board, a display panel, and a driving chip. The display panel and the driving chip are usually electrically connected to the circuit board through anisotropic conductive films.

### BRIEF DESCRIPTION OF THE DRAWINGS

Implementations of the present technology will now be described, by way of embodiment, with reference to the attached figures.

FIG. 1 is a cross-sectional view of an embodiment of a double-sided copper clad substrate according to the present disclosure.

FIG. 2 is a cross-sectional view showing a wiring substrate formed from the double-sided copper clad substrate of FIG. 1.

FIG. 3 is a cross-sectional view showing a first side plate formed on a side of the wiring substrate of FIG. 2.

FIG. 4 is a cross-sectional view showing a first hole formed on the first side plate of FIG. 3.

FIG. 5 is a cross-sectional view showing a first cover layer formed on the first side plate of FIG. 4.

FIG. 6 is a cross-sectional view showing a first conductive body formed in the first hole of FIG. 5.

FIG. 7 is a cross-sectional view of an embodiment of a display module according to the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “connected” is defined as connected, whether directly or indirectly through intervening components, and is not necessarily limited to physical connections. The connection can be such that the objects are permanently connected or releasably connected. The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising,” when utilized, means “including, but not necessarily limited to”; it specifically indicates open-ended inclusion or membership in the so-described combination, group, series, and the like.

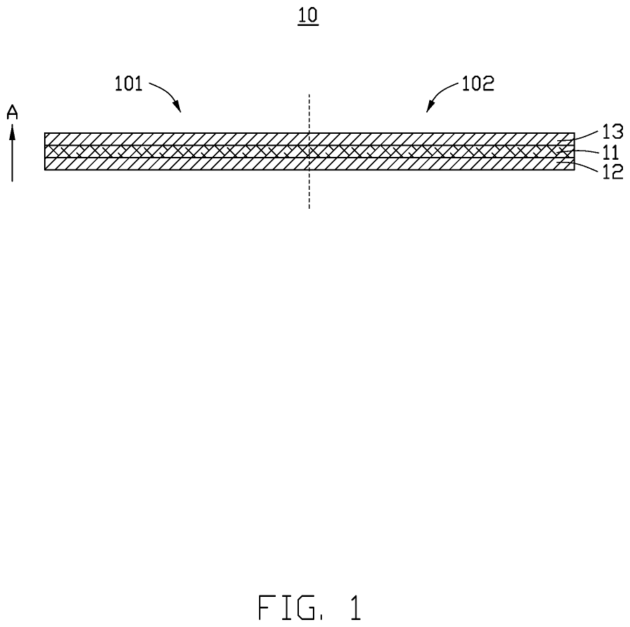

Referring to FIGS. 1 to 5, a method for manufacturing a circuit board 100 is illustrate. The method includes steps as follows.

Step S1, referring to FIG. 1, a double-sided copper clad substrate 10 is provided. The double-sided copper clad substrate 10 includes an insulation layer 11, a first copper foil layer 12, and a second copper foil layer 13. The first copper foil layer 12 is disposed on a surface of the insulation layer 11, and the second copper foil layer 13 is disposed on a surface of the insulation layer 11 facing away from the first copper foil layer 12. In a direction perpendicular to the thickness direction indicated by arrow A in FIG. 1, the double-sided copper clad substrate 10 is divided into a first area 101 and a second area 102 other than the first area 101.

The insulation layer 11 is made of polyimide (PI), thermoplastic polyimide (TPI), polyethylene terephthalate (PET), polyethylene naphthalate (PEN), polyethylene (PE), or polyvinyl chloride polymer (PVC). In the embodiment, the insulation layer 11 is made of PI.

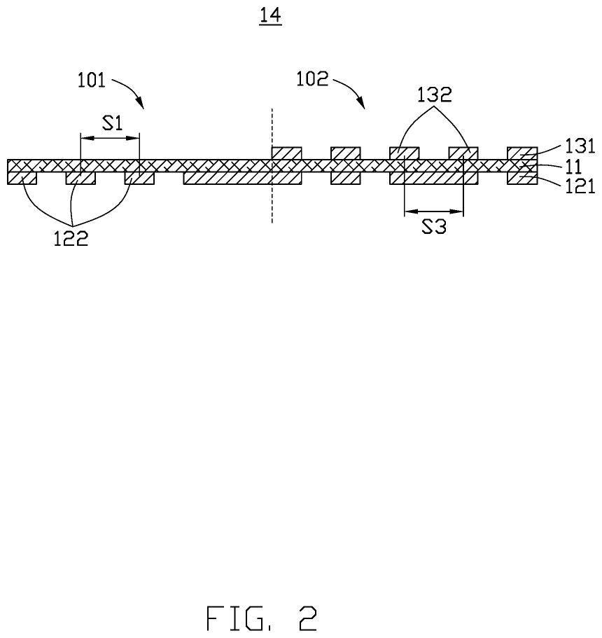

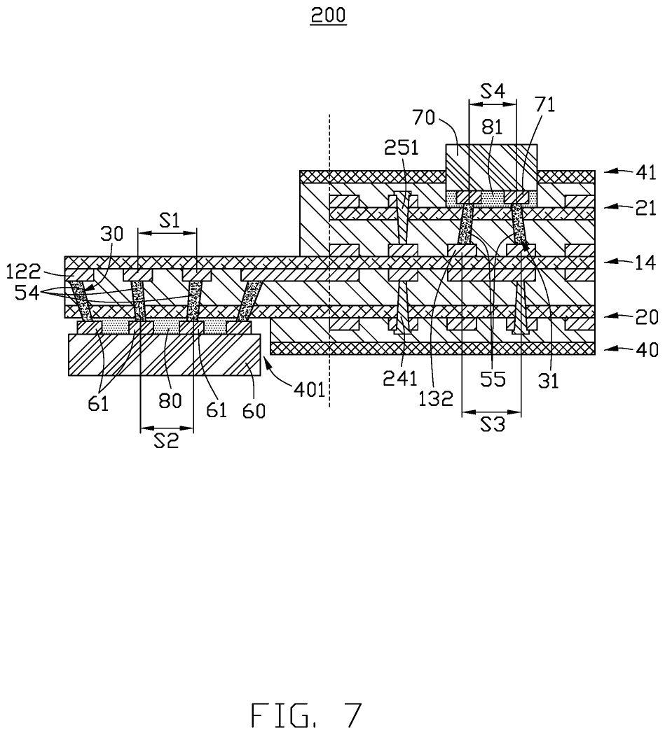

Step S2, referring to FIG. 2, the first copper foil layer 12 is etched to form a first inner wiring layer 121, and the second copper foil layer 13 is etched to form a second inner wiring layer 131, thereby obtaining an inner wiring substrate 14. The first inner wiring layer 121 covers the entire insulation layer 11 in the first area 101 and the second area 102. The second copper foil layer 13 in the first area 101 is removed by etching, and the second inner wiring layer 131 only covers the insulation layer 11 in the second area 102. The first inner wiring layer 121 in the first area 101 includes a plurality of first connection pads 122 which are spaced apart from each other. The first connection pads 122 are configured to connect an external component, such as a display panel 60 (shown in FIG. 7). The second inner wiring layer 131 in the second area 102 includes a plurality of second connection pads 132. The second connection pads 132 are configured to connect an external component, such as a driving chip 70 (shown in FIG. 7). The plurality of first connection pads 122 are arranged side by side in the first area 101, and the plurality of second connection pads 132 are arranged side by side in the second area 102. There is a first central distance S1 between two adjacent first connection pads 122, and there is a third central distance S3 between two adjacent second connection pads 132. The first central distance S1 is a distance between central positions of two adjacent first connection pads 122, and the second third central distance S3 is a distance between central positions of two adjacent second connection pads 132.

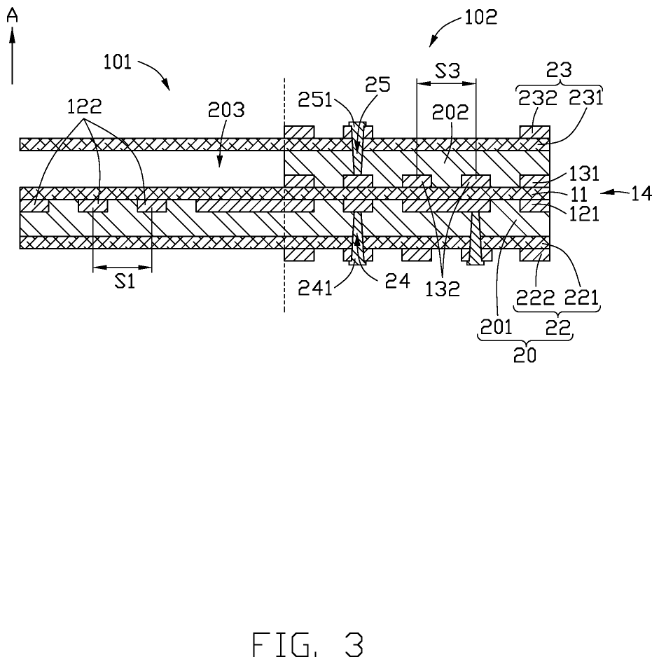

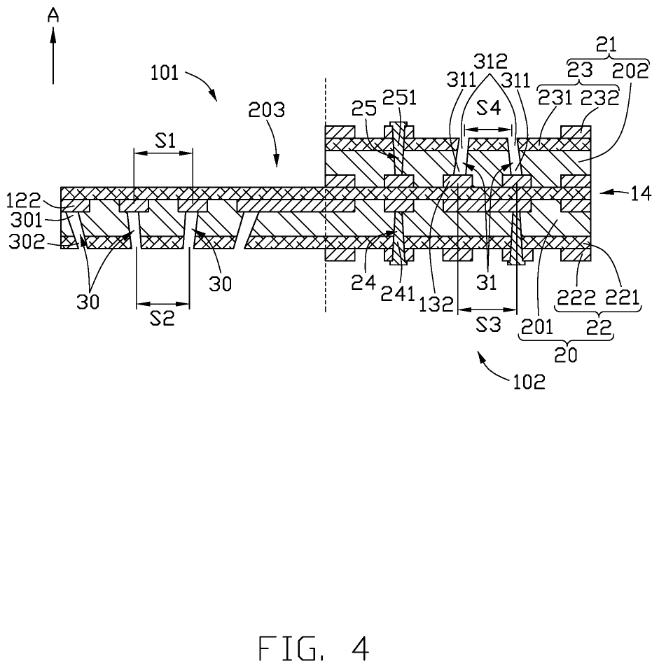

Step S3, referring to FIG. 3 and FIG. 4, a first side plate 20 and a second side plate 21 are respectively formed on the first inner wiring layer 121 and the second inner wiring layer 131, the first side plate 20 covers the plurality of first connection pads 122, and the second side plate 21 covers the plurality of second connection pads 132.

In the embodiment, step S3 includes steps as follows.

Step S31, a first adhesive layer 201 is formed on the first inner wiring layer 121, and a second adhesive layer 202 is formed on the second inner wiring layer 131. The first adhesive layer 201 covers the plurality of first connection pads 122. The second adhesive layer 202 covers the plurality of second connection pads 132. The second adhesive layer 202 defines a through hole 203. The through hole 203 corresponds in position to the first area 101.

Step S32, a first wiring substrate 22 is formed on the first adhesive layer 201, and a second wiring substrate 23 is formed on the second adhesive layer 202. The first wiring substrate 22 includes a second insulation layer 221 and a first outer wiring layer 222. The second insulation layer 221 is sandwiched between the first outer wiring layer 222 and the first adhesive layer 201. The first wiring substrate 22 and the first adhesive layer 20 constitute the first side plate 20. The second wiring substrate 23 includes a third insulation layer 231 and a second outer wiring layer 232. The third insulation layer 231 is sandwiched between the second outer wiring layer 232 and the second adhesive layer 202. The second wiring substrate 23 and the second adhesive layer 202 constitute the second side plate 21.

Step S33, a first hole 24 and a second hole 25 are formed on the first side plate 20 and the second side plate 21 respectively. The first hole 24 penetrates the first wiring substrate 22 and the first adhesive layer 201, and a portion of the first inner wiring layer 121 is exposed from the first hole 24. The second hole 24 penetrates the second wiring substrate 23 and the second adhesive layer 202, and a portion of the second inner wiring layer 131 is exposed from the second hole 25. The first hole 24 and the second hole 25 are staggered with respect to the first area 101.

Step S34, a first conductive body 241 is formed in the first hole 24, and a second conductive body 251 is formed in the second hole 25. The first conductive body 241 electrically connects the first inner wiring layer 121 to the first outer wiring layer 222. The second conductive body 251 electrically connects the second inner wiring layer 131 to the second outer wiring layer 232. The first conductive body 241 and the second conductive body 251 are formed by electroplating. The first conductive body 241 and the second conductive body 251 may be formed by electroless-depositing copper.

Step S4, referring to FIG. 4, a plurality of first holes 30 are formed on the first side plate 20 corresponding to the first area 101, and a plurality of second holes 31 are formed on the second side plate 21 corresponding to the second area 102. Each of the first connection pads 122 is exposed from a corresponding first hole 30. Each of the second connection pads 132 is exposed from a corresponding second hole 31. Each of the first holes 30 includes a first end 301 facing the corresponding first connection pad 122, and a second end 302 facing away from the corresponding first connection pad 122. Each of the second holes 31 includes a third end 311 facing the corresponding second connection pad 132, and a fourth end 312 facing away from the corresponding second connection pad 132. There is a second central distance S2 between two adjacent second ends 302, and there is a fourth central distance S4 between two adjacent fourth ends 312. The second central distance S2 is a distance between central positions of two adjacent second ends 302, and the fourth central distance S4 is a distance between central positions of two adjacent fourth ends 312. The first central distance S1 is greater than the second central distance S2, and the third central distance S3 is greater than the fourth central distance S4.

At least some of the first holes 30 are inclined with respect to the thickness direction A. Alternatively, at least some of the second holes 31 are inclined with respect to the thickness direction A. Therefore, the first connection pads 122 with a large distance between two adjacent first connection pads 122 can be connected to connection terminals (such as pins of the display panel 60) with a small distance between two adjacent connection terminals, and the second connection pads 132 with a large distance between two adjacent second connection pads 132 can be connected to connection terminals (such as pins of the driving chip 70) with a small distance between two adjacent connection terminals.

In the embodiment, the first holes 30 and the second holes 31 are formed by laser drilling or mechanical drilling.

Referring to FIG. 3 and FIG. 4, a portion of the second wiring substrate 23 corresponding to the first area 101 is further removed. In other words, a portion of the second wiring substrate 23 corresponding to the through hole 203 is remove, thereby exposing a portion of the inner wiring substrate 14. The portion of the second wiring substrate 23 is removed by laser drilling or mechanical drilling.

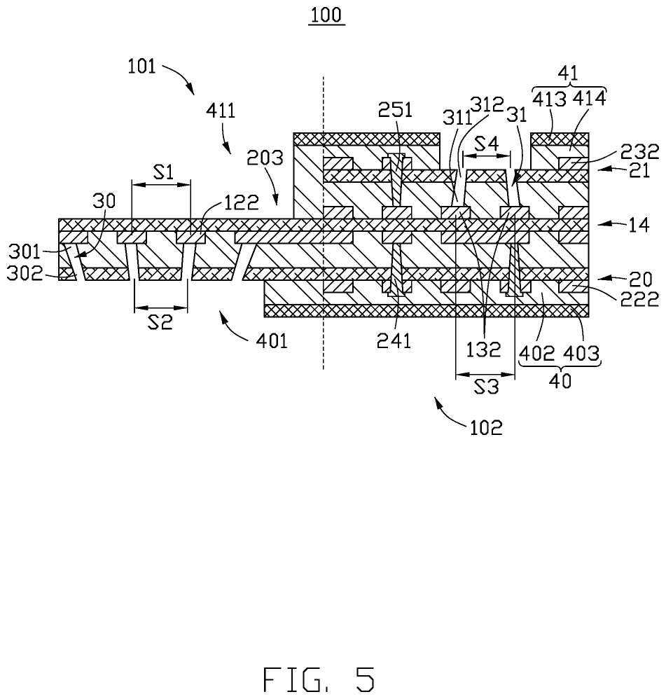

Step S5, referring to FIG. 5, a first cover layer 40 is formed on a side of the first side plate 20 facing away from the inner wiring substrate 14, and a second cover layer 41 is formed on a side of the second side plate 21 facing away from the inner wiring substrate 14, thereby obtaining the circuit board 100. The first cover layer 40 is formed on a surface of the first outer wiring layer 222. The second cover layer 41 is formed on a surface of the second outer wiring layer 232. The first cover layer 40 defines a first opening 401 exposing the second ends 302 of the first holes 30. The second cover layer 41 defines a third opening 411 and a second opening 412. The third opening 411 penetrates the second cover layer 41 and corresponds in position to the first area 101. The second opening 412 penetrates the second cover layer 41, and the fourth ends 312 of the second holes 31 are exposed from the second opening 412. A portion of the second cover layer 41 extends into the through hole 203 to cover a portion of the inner wiring substrate 14 exposed from the through hole 203, which is conducive to protecting a side surface of the second side plate 21.

The first cover layer 40 includes a first adhering layer 402 and a first solder mask 403, and the first adhering layer 402 is sandwiched between the first outer wiring layer 222 and the first solder mask 403. The second cover layer 41 includes a second adhering layer 414 and a second solder mask 413, and the second adhering layer 414 is sandwiched between the second outer wiring layer 232 and the second solder mask 413.

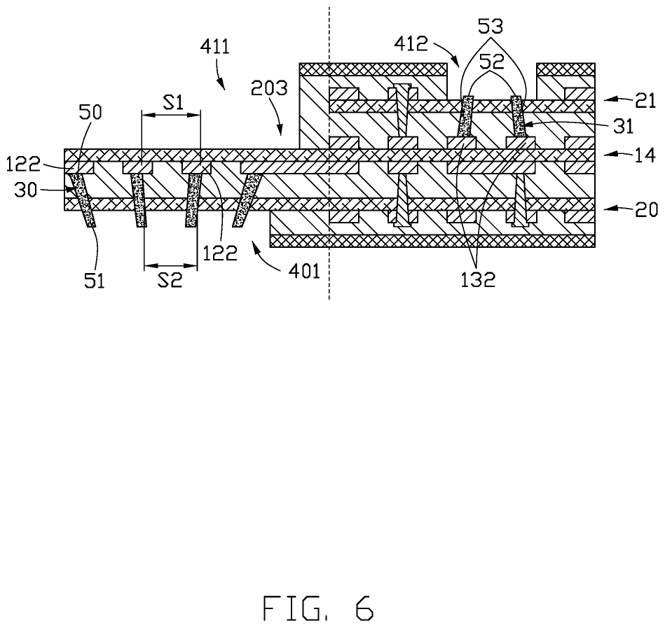

Step S6, referring to FIG. 6, the first holes 30 are infilled with a conductive paste to form first conductive bodies 54, and the second holes 31 are infilled with a conductive paste to form second conductive bodies 55. Each of the first conductive bodies 54 is electrically connected to the corresponding first connection pad 122, and an end of each of the first conductive bodies 54 extends out of the corresponding first hole 30 to form a first connection portion 51. Each of the second conductive bodies 55 is connected to the corresponding second connection pad 132, and an end of each second conductive body 55 extends out of the corresponding second hole 31 to form a second connection portion 53.

In the method for manufacturing the circuit board 100, the first conductive bodies 54 arranged on the first side plate 20 are inclined, and a distance between two adjacent first connection portions 51 is smaller than a distance between two adjacent first connection pads 122, so that the circuit board 100 with a normal size can be electrically connected to the display panel 60 with a small size through the first conductive bodies 54. The second conductive bodies 55 arranged on the second side plate 21 are inclined, and a distance between two adjacent second connection portion 53 is smaller than a distance between two adjacent second connection pads 132, so that the circuit board 100 with a normal size can be electrically connected to the driving chip 70 with a small size through the second conductive bodies 55. The through hole 20 is provided on the second side plate 21 to expose the first area 101 of the inner wiring substrate 14, thereby facilitating the bending of the exposed first area 101.

Referring to FIG. 6, the circuit board 100 includes the inner wiring substrate 14 and the first side plate 20 disposed on a surface of the inner wiring substrate 14. The inner wiring substrate 14 includes the plurality of first connection pads 122 which are arranged at intervals on one side of the inner wiring substrate 14. The first side plate 20 covers the plurality of first connection pads 122. The first side plate 20 defines the plurality of first holes 30 for exposing the plurality of first connection pads 122. Each of the first holes 30 includes the first end 301 facing the corresponding first connection pad 122, and the second end 302 facing away from the corresponding first connection pad 122. The first central distance S1 between two adjacent first connection pads 122 is greater than the second central distance S2 between two adjacent second ends 302. The plurality of first conductive bodies 54 respectively infill the plurality of first holes 30 and are electrically connected to the first connection pads 122. Ends of the first conductive bodies 54 facing away from the first connection pads 122 extend out of the first holes 30 to form the first connection portions 51.

The inner wiring substrate 14 further includes the plurality of second connection pads 132 which are arranged at intervals on a side of the inner wiring substrate 14 facing away from the first connection pads 122. The circuit board 100 further includes the second side plate 21 disposed on the second connection pads 132. The second side plate 21 defines the plurality of second holes 31 for exposing the plurality of second connection pads 132. Each of the second holes 31 includes the third end 311 facing the corresponding second connection pad 132, and the fourth end 312 facing away from the corresponding second connection pad 132. The third central distance S3 between two adjacent second connection pads 132 is greater than the fourth central distance S4 between two adjacent fourth ends 312. The plurality of second conductive bodies 55 respectively infill the plurality of second holes 31 and are electrically connected to the second connection pads 132. Ends of the second conductive bodies 55 facing away from the second connection pads 132 extend out of the second holes 31 to form the second connection portions 53.

Referring to FIGS. 3-6, the second side plate 21 defines the through hole 203 penetrating the second adhesive layer 202 and the second wiring substrate 23 to expose a portion of the inner wiring substrate 14. The second inner wiring layer 131 only covers a portion of the insulation layer 11 which does not correspond to the through hole 203. In other words, only a portion of the insulation layer 11 is exposed from the through hole 203, but the second inner wiring layer 131 is not exposed from the through hole 203. The through hole 203 corresponds in position to the plurality of first connection pads 122. The second cover layer 41 defines the third opening 411 exposing the through hole 203. The second cover layer 41 further extends into the through hole 203 to cover the portion of the inner wiring substrate 14 exposed from the through hole 203.

Referring to FIG. 7, a method for manufacturing a display module is illustrated. The method includes steps as follows.

Step S7, referring to FIG. 7, the display panel 60 is mounted in the first opening 401, and the driving chip 70 is mounted in the second opening 412. The display panel 60 includes a plurality of first connection terminals 61. The plurality of first connection terminals 61 connect to the plurality of first connection portion 51 one to one, such that the display panel 60 is electrically connected to the first connection pads 122. The driving chip 70 includes a plurality of second connection terminals 71. The plurality of second connection terminals 71 connect to the plurality of second connection portion 53 one to one, such that the driving chip 70 is electrically connected to the second connection pads 132.

Step S8, a first encapsulation body 80 is formed in a gap between the display panel 60 and the first side plate 20, and a second encapsulation body 81 is formed in a gap between the driving chip 70 and the second side plate 21, thereby obtaining the display module 200. The first encapsulation body 80 is configured to strengthen the connection between the display panel 60 and the first side plate 20. The second encapsulation body is configured to strengthen the connection between the driving chip 70 and the second side plate 21.

Referring to FIG. 6 and FIG. 7, the display module 200 includes the circuit board 100, the display panel 60, the plurality of first conductive bodies 54, the plurality of second conductive bodies 55 and the driving chip 70. The circuit board 100 includes the inner wiring substrate 14, the first side plate 20, and the second side plate 21. The first side plate 20 and the second side plate 21 are disposed on opposite surfaces of the inner wiring substrate 14. The inner wiring substrate 14 includes the plurality of first connection pads 122 on one side and the plurality of second connection pads 132 on the other side. The display panel 60 is disposed on the first side plate 20 and includes the plurality of first connection terminals 61. The driving chip 70 is disposed on the second side plate 21 and includes the plurality of second connection terminals 71. A central distance between two adjacent first connection pads 122 is greater than a central distance between two adjacent first connection terminals 61, and the first connection terminals 61 are electrically connected to the first connection pads 122 through the first conductive bodies 54 penetrating the first side plate 20. A central distance between two adjacent second connection pads 132 is greater than a central distance between two adjacent second connection terminals 71, and the second connection terminals 71 are electrically connected to the second connection pads 132 through the second conductive bodies 55 penetrating the second side plate 21.

While the present disclosure has been described with reference to particular embodiments, the description is illustrative of the disclosure and is not to be construed as limiting the disclosure. Therefore, those of ordinary skill in the art can make various modifications to the embodiments without departing from the scope of the disclosure as defined by the appended claims.

What is claimed is:

1. A method for manufacturing a circuit board, comprising:
providing an inner wiring substrate, the inner wiring substrate comprising a plurality of first connection pads at a side, the plurality of first connection pads being spaced apart from each other;
forming a first side plate on a surface of the inner wiring substrate, the first side plate covering the plurality of first connection pads;
forming a plurality of first holes penetrating the first side plate, the plurality of first holes exposing the plurality of first connection pads, each of the plurality of first holes comprising a first end facing a corresponding first connection pad of the plurality of first connecting pads and a second end facing away from the corresponding first connection pad, wherein a central distance between two adjacent first connection pads is greater than a center distance between two second ends of two adjacent first holes; and
forming a plurality of first conductive bodies in the plurality of first holes, the plurality of first conductive bodies being electrically connected to the plurality of first connection pads, ends of the plurality of first conductive bodies facing away from the plurality of first connection pads extending out of the plurality of first holes to form a plurality of first connection portions.

2. The method of claim 1, wherein forming a first side plate on a surface of the inner wiring substrate comprises:
forming a first adhesive layer on a surface of the inner wiring substrate, the first adhesive layer covering the plurality of first connection pads; and
forming a first wiring substrate on a surface of the first adhesive layer.

3. The method of claim 1, wherein the inner wiring substrate further comprises a plurality of second connection pads at another side, the plurality of second connection pads being spaced apart from each, and the method further comprises:
forming a second side plate on another surface of the inner wiring substrate, the second side plate covering the plurality of second connection pads;
forming a plurality of second holes penetrating the second side plate, the plurality of second holes exposing the plurality of second connection pads, each of the plurality of second holes comprising a third end facing a corresponding second connection pad of the plurality of second connection pads and a fourth end facing away from the corresponding second connection pad, wherein a central distance between two adjacent second connection pads is greater than a center distance between two fourth ends of two adjacent second holes; and
forming a plurality of second conductive bodies in the plurality of second holes, the plurality of second conductive bodies being electrically connected to the plurality of second connection pads, ends of the plurality of second conductive bodies facing away from the plurality of second connection pads extending out of the plurality of second holes to form a plurality of second connection portions.

4. The method of claim 3, wherein forming a second side plate on another surface of the inner wiring substrate comprises:
forming a second adhesive layer on another surface of the inner wiring substrate, the second adhesive layer covering the plurality of second connection pads; and
forming a second wiring substrate on a surface of the second adhesive layer.

5. The method of claim 4, further comprising:
forming a through hole, the through hole penetrating the second adhesive layer to expose the inner wiring substrate and corresponding in position to the plurality of first connection pads; and
removing a portion of the second wiring substrate corresponding to the through hole.

6. The method of claim 5, further comprising:
forming a first cover layer on a side of the first side plate facing away from the inner wiring substrate, the first cover layer defining a first opening exposing the plurality of first conductive bodies; and
forming a second cover layer on a side of the second side plate facing away from the inner wiring substrate, the second cover layer defining a second opening exposing the plurality of second conductive bodies.

7. The method of claim 6, wherein the second cover layer extends into the through hole to cover a portion of the inner wiring substrate exposed from the through hole.

8. A circuit board comprising:
an inner wiring substrate, the inner wiring substrate comprising a plurality of first connection pads at a side, the plurality of first connection pads being spaced apart from each other;
a first side plate disposed on a surface of the inner wiring substrate, the first side plate covering the plurality of first connection pads and defining a plurality of first holes exposing the plurality of first connection pads, each of the plurality of first holes comprising a first end facing a corresponding first connection pad of the plurality of first connection pads and a second end facing away from the corresponding first connection pad, wherein a central distance between two adjacent first connection pads is greater than a center distance between two second ends of two adjacent first holes; and
a plurality of first conductive bodies filling the plurality of first holes, the plurality of first conductive bodies being electrically connected to the plurality of first connection pads, ends of the plurality of first conductive bodies facing away from the plurality of first connection pads extending out of the plurality of first holes to form a plurality of first connection portions.

9. The circuit board of claim 8, wherein the first side plate comprises a first adhesive layer and a first wiring substrate, the first adhesive layer is sandwiched between the inner wiring substrate and the first wiring substrate.

10. The circuit board of claim 8, wherein the inner wiring substrate further comprises a plurality of second connection pads at another side, the plurality of second connection pads being spaced apart from each, the circuit board further comprises:
a second side plate disposed on another surface of the inner wiring substrate, the second side plate covering the plurality of second connection pads and defining a plurality of second holes exposing the plurality of second connection pads, each of the plurality of second holes comprising a third end facing a corresponding second connection pad of the plurality of second connection pads and a fourth end facing away from the corresponding second connection pad, wherein a central distance between two adjacent second connection pads is greater than a center distance between two fourth ends of two adjacent second holes; and
a plurality of second conductive bodies filling the plurality of second holes, the plurality of second conductive bodies being electrically connected to the plurality of second connection pads, ends of the plurality of second conductive bodies facing away from the plurality of second connection pads extending out of the plurality of second holes to form a plurality of second connection portions.

11. The circuit board of claim 10, wherein the second side plate comprises an adhesive layer and a wiring substrate, the adhesive layer is sandwiched between the inner wiring substrate and the wiring substrate.

12. The circuit board of claim 11, wherein the second side plate defines a through hole penetrating the wiring substrate and the adhesive layer, the through hole corresponds in position to the plurality of first connection pads.

13. The circuit board of claim 12, further comprising:
a first cover layer disposed on a side of the first side plate facing away from the inner wiring substrate, the first cover layer defining a first opening exposing the plurality of first conductive bodies; and
a second cover layer disposed on a side of the second side plate facing away from the inner wiring substrate, the second cover layer defining a second opening exposing the plurality of second conductive bodies.

14. The circuit board of claim 13, wherein the second cover layer extends into the through hole to cover a portion of the inner wiring substrate exposed from the through hole.

15. A display module comprising:
a display panel, the display panel comprising a plurality of first connection terminals; and
a circuit board, the circuit board comprising:
an inner wiring substrate, the inner wiring substrate comprising a plurality of first connection pads at a side, the plurality of first connection pads being spaced apart from each other,
a first side plate disposed on a surface of the inner wiring substrate, the first side plate covering the plurality of first connection pads and defining a plurality of first holes exposing the plurality of first connection pads, each of the plurality of first holes comprising a first end facing a corresponding first connection pad of the plurality of first connection pads and a second end facing away from the corresponding first connection pad, wherein a central distance between two first connection pads is greater than a center distance between two second ends of two adjacent first holes, and
a plurality of first conductive bodies filling the plurality of first holes, the plurality of first conductive bodies being electrically connected to the plurality of first connection pads, ends of the plurality of first conductive bodies facing away from the plurality of first connection pads extending out of the plurality of first holes to form a plurality of first connection portions, wherein the display panel is disposed on the first side plate, and the plurality of first connection portions is electrically connected to the plurality of first connection terminals.

16. The display of claim 15, wherein the first side plate comprises a first adhesive layer and a first wiring substrate, the first adhesive layer is sandwiched between the inner wiring substrate and the first wiring substrate.

17. The display module of claim 15, further comprising a driving chip, the driving chip comprising a plurality of second connection terminals, wherein the inner wiring substrate further comprises a plurality of second connection pads at another side, the plurality of second connection pads being spaced apart from each, the circuit board further comprises:
a second side plate disposed on another surface of the inner wiring substrate, the second side plate covering the plurality of second connection pads and defining a plurality of second holes exposing the plurality of second connection pads, each of the plurality of second holes comprising a third end facing a corresponding second connection pad of the plurality of second connection pads and a fourth end facing away from the corresponding second connection pad, wherein a central distance between two adjacent second connection pads is greater than a center distance between two fourth ends of two adjacent second holes, and
a plurality of second conductive bodies filling the plurality of second holes, the plurality of second conductive bodies being electrically connected to the plurality of second connection pads, ends of the plurality of second conductive bodies facing away from the plurality of second connection pads extending out of the plurality of second holes to form a plurality of second connection portions, wherein the plurality of second connection portions is electrically connected to the plurality of second connection terminals.

18. The display module of claim 17, wherein a central distance between two adjacent first connection pads is greater than a central distance between two adjacent first connection terminals, and a central distance between two adjacent second connection pads is greater than a central distance between two adjacent second connection terminals.

19. The display module of claim 17, wherein the second side plate defines a through hole exposing the inner wiring substrate, the through hole corresponds in position to the plurality of first connection pads.

20. The display module of claim 19, wherein the circuit board further comprises:
a first cover layer disposed on a side of the first side plate facing away from the inner wiring substrate, the first cover layer defining a first opening exposing the plurality of first conductive bodies; and
a second cover layer disposed on a side of the second side plate facing away from the inner wiring substrate, the second cover layer defining a second opening exposing the plurality of second conductive bodies, wherein the second cover layer extends into the through hole to cover a portion of the inner wiring substrate exposed from the through hole.
